(19) United States
(12) Patent Application Publication
(10) Pub. No.: US 2026/0247865 A1
(43) Pub. Date: Aug. 20, 2026

(54) ACTUATOR MODULE

(71) Applicant: VERMES MICRODISPENSING GMBH, Holzkirchen (DE)

(72) Inventors: Mario FLIESS, München (DE); Simon SCHMIDBERGER, Bruckmühl (DE); Wolfram HELLMICH, Baldham (DE)

(73) Assignee: VERMES MICRODISPENSING GMBH, Holzkirchen (DE)

(21) Appl. No.: 19/489,501

(22) PCT Filed: May 29, 2024
(86) PCT No.: PCT/EP2024/064765

§ 371 Date: Dec. 2, 2025

(30) Foreign Application Priority Data
Jun. 13, 2023 (DE) 10 2023 115 413.3

(51) Int. Cl. H10N 30/88; H10N 30/50

(52) U.S. Cl. CPC H10N 30/883; H10N 30/50

(57) ABSTRACT

The invention relates to an actuator module (1) with a hermetically sealed module housing (3), which extends longitudinally in an axial direction (R_{AX}), with at least one piezo actuator (2) arranged in the module housing (3) and with electrical terminals (6a, 6b) at least for the piezo actuator (2), which terminals (6a, 6b) are fed through a module housing wall (3w), wherein a module housing interior space (3i) between the piezo actuator (2) and the module housing wall (3w) comprises a potting compound (4), which electrically insulates the module housing wall (3w) from the piezo actuator (2) and which is formed in a heat-conducting manner, in particular with a heat-conducting auxiliary substance, wherein the module housing wall (3w) of the module housing (3) has a bellows (10, 20, 30, 40) with a wave contour (10, 20, 30, 40), wherein at least one section (14, 34l, 34r, 44l, 44r) of the wave contour (10, 20, 30, 40) is formed in a helix-shaped manner in the axial direction (R_{AX}). The invention further relates to a metering system (50) with such an actuator module (1).

The invention relates to an actuator module with a hermetically sealed module housing, which extends longitudinally in an axial direction, with at least one piezo actuator arranged in the housing and with electrical terminals at least for the piezo actuator and a metering system with such an actuator module.

Piezoceramic multilayer actuators or piezo actuators, in short, consist of a plurality of stacked thin layers of a piezoelectric material, e.g., lead zirconate titanate. In the case of such multilayer piezo actuators (also referred to as “multilayer elements” or “piezo stack”), a cascading takes place in that several thin piezo elements with inner electrodes lying therebetween are joined together. The inner electrodes are alternatingly fed to a surface of the piezo actuator, wherein two outer electrodes connect the respective inner electrodes. The inner electrodes are electrically connected in parallel and are combined to form two groups, which form the connection poles of the piezo actuator. When applying an electrical voltage to the connection poles, said electrical voltage is transmitted to the inner electrodes in parallel and effects an electrical field via this in the layers of the piezoelectric material. The sum of the mechanical deformations of the individual layers of the piezoelectric material results in the usable expansion and/or force of the piezo actuator.

Piezo actuators are used in different technical fields, e.g., in actuating and positioning drives or in metering systems for the targeted metering of liquid to viscous metering substances, in particular in so-called jet valves. Particular advantages of piezo actuators are, for example, that they have a large stiffness and compressive strength, provide for a high position resolution, display a quick response behavior and effect high accelerations and generally operate without wear.

Regardless of these advantages, the heat dissipation of piezo actuators has often turned out to be insufficient in the past. In particular in the case of piezo actuators, which are arranged in a casing for protection against external influences, e.g., a closed housing with a piezo actuator located therein, it may happen that a sufficient heat dissipation from the piezo actuator is not ensured during operation. The temperature of a piezo actuator can have an effect on the geometry of the piezo actuator in any control state, for instance on the longitudinal extension thereof in an (unswitched) rest state.

As a result of a thermally induced length change, in particular due to an insufficient heat dissipation from the piezo actuator during operation, the longitudinal extension of the piezo actuator effected as a result of a connection of the piezo actuator and/or a generated force and/or a position of the piezo actuator within a machine can deviate from a specific target value. Due to the fact that a particularly high precision is required in many applications during operation of the piezo actuator, a temperature-induced length change of a piezo actuator is to be avoided, if possible.

Known piezo actuators, in particular piezo actuators, which are arranged in a tightly sealed casing, for example in a metallic module housing, optionally by using a specific, e.g., water-absorbent medium in the module housing, can thus only be used to a limited extent in many technical fields. In particular in the case of the above-mentioned jet valves, which currently typically operate at a high clock frequency of more than 1 kHz, wherein a correspondingly large lost heat develops in the piezo actuator, an actuator module is desirable, which provides for a sufficient heat dissipation from the surface of the piezo actuator and simultaneously provides for an effective protection of the piezo actuator against damaging environmental conditions for a reliable operation.

It is the object of the present invention to provide an actuator module with a hermetically sealed housing as well as a metering system with such an actuator module, by means of which the above-described disadvantages can be avoided or at least reduced.

This object is solved by means of an actuator module according to patent claim 1 and a metering system according to patent claim 10.

An actuator module according to the invention has a hermetically tightly, in particular an inherently tightly, sealed module housing. The module housing extends longitudinally, in particular in the longitudinal direction, in an axial direction. In other words, the direction of a longest extension of the module housing is referred to as axial direction. The axial direction is preferably parallel to the longitudinal extension of the piezo actuator, which is arranged in the module housing. The module housing is preferably longer in the axial direction than in a direction, which is orthogonal to the axial direction. The module housing can preferably be formed or shaped, respectively, essentially “hollow cylindrically”, thus have a round cross section.

At least one piezo actuator, which is preferably encapsulated completely in a hermetically tight manner, is arranged in an interior of the module housing. It can be aligned, for example, centrally therein. On principle, however, it is also conceivable that two or more piezo actuators are enclosed in a hermetically tight manner in the same module housing. For example, two separately controllable piezo actuators could be arranged essentially parallel to one another in the same module housing. Without being limited thereto and unless mentioned otherwise, the invention will be described below on the basis of a module housing with only one piezo actuator.

The piezo actuator can in particular be a piezoceramic multilayer actuator, which has a plurality of layers in the longitudinal direction. The actuator module has at least two electrical terminals at least for the piezo actuator. The electrical terminals are fed through a module housing wall of the module housing, in particular in a hermetically tight and electrically insulated manner.

In the context of the invention, the term “hermetically” sealed is understood so that the module housing is formed so that no substances can pass through the module housing or no substances can pass through the sealed module housing, respectively. The module housing is “hermetically” sealed so that no solids and/or no liquids and/or no gases can enter into the module housing from the outside during operation of the actuator module. In this respect, the hermetically sealed module housing can also be referred to as impermeable module housing, which is constructed to be so impermeable that nothing can enter or exit. The module housing preferably forms an “absolutely tight” enclosure or inclusion, respectively, of the piezo actuator with respect to an environment of the module housing, i.e., piezo actuator is surrounded or encased, respectively, by the module housing on the other side. An “absolutely tight” module housing is understood such that in particular an exchange of air and/or water molecules is prevented via the module housing. The module housing can accordingly be “absolutely tight” for a certain operating time at least (relatively) with regard to air and/or water molecules, in particular in order to prevent a long-term diffusion of water molecules through the materials of the module housing during operation. The tightness of the module housing can be analyzed, e.g., via a helium leak test. The module housing can in particular be a deep-drawn module housing, as will be described later.

The module housing thus differs from known casings, such as, for example, metal sleeves, which are only pushed onto a piezo actuator, wherein individual piezo actuator regions, such as, e.g., an actuator end, then protrude from the sleeve. Such sleeves are thus not a “hermetically” sealed module housing in terms of the invention.

A potting compound, which electrically insulates the module housing wall, in particular during operation of the piezo actuator, with respect to the piezo actuator, is further arranged in a housing interior space in the interior of the module housing between the piezo actuator, in particular a surface of the piezo actuator, and the module housing wall. An insulation resistance of the base components of the potting compound, in particular of a base compound, e.g., a silicone gel, is preferably at least 1·10¹² Ω·cm, preferably at least 1·10¹⁵ Ω·cm, in particular at least 1·10¹⁶ Ω·cm or more.

It should be mentioned explicitly at this point once again that in the case of more than one piezo actuator in the module housing interior space, the potting compound can then be introduced between the respective piezo actuators as well as around the piezo actuators between the module housing wall and the respective piezo actuators.

According to the invention, the potting compound is formed in a heat-conducting manner. The potting compound is preferably formed in a heat-conducting manner so that the heat generated by the piezo actuator during operation can be dissipated from the inside, in particular from a piezo actuator surface, through the potting compound, to the outside to the module housing wall. The heat dissipated from the piezo actuator can in particular be lost heat, which is created during operation of the piezo actuator. The potting compound can preferably comprise at least one heat-conducting auxiliary substance for forming a heat conductivity of the potting compound.

A heat conductivity of the potting compound (in the module housing interior space) can be at least 0.5 W/(m·K), preferably at least approximately 1.0 W/(m·K), preferably at least approximately 1.5 W/(m™K), more preferably at least approximately 2.0 W/(m·K), particularly preferably at least approximately 2.25 W/(m·K), in particular at least approximately 2.45 W/(m·K).

The module housing wall of the module housing thereby further has a bellows with a wave contour. It can be provided that only a specific portion of the module housing wall has a bellows, wherein at least one region of the housing wall is then formed without bellows. For example, the front sides of the module housing, which delimit the module housing in the axial direction, can be formed without bellows. A wave contour is understood here to be a wave-shaped structure of the module housing wall and/or of an, in particular outer, surface of the module housing wall, which alternately has sinks or depressions, respectively, and elevations in the axial direction of the module housing. The respective depressions can preferably be formed in a concave manner and the respective elevations can be formed in a convex manner. In the axial direction between a first (e.g., the upper) front side or head side, respectively (having the electric terminals) and a second (e.g., closed, lower) front side or end side, respectively, in particular lying opposite the first front side, of the module housing wall, the bellows can preferably be formed as integral jacket surface of the module housing wall.

As is also described once again further below in more detail in the context of the explanation of a metering system according to the invention with at least one such actuator module, the module housing wall with the bellows is formed for encasing a piezo actuator, which is installed or can be installed, respectively, in a cylindrical recess in a housing of a metering system, preferably so as to fit accurately.

According to the invention, at least one section of the wave contour of the bellows is formed in a helix-shaped or coil-shaped manner, respectively, in the axial direction of the module housing or with respect to the axial direction, respectively. This means that the section has at least one coil-shaped elevation, which, together with an adjoining coil-shaped depression, in particular in the form of a groove, winds proportionately along the (external) module housing wall of the module housing in the circumferential direction (of the module housing) as well as in the axial direction (of the module housing)

A section formed in a helix-shaped manner can preferably have at least one, preferably concave, groove-like depression, which is encased on both side by a respective adjoining, preferably convex, elevation, wherein the groove-like depression forms a curve, which winds with a, preferably consistent, gradient, around the outer circumference of the module housing. Such a groove-like depression can preferably form a helix in the module housing wall (which faces outwards).

The section, which is formed in a helix-shaped manner, can accordingly have at least one helix or helix structure, respectively, in particular in the form of a groove-like depression in the module housing wall (which faces outwards). At least the region of the module housing wall, which comprises the section formed in a helix-shaped manner, is preferably formed in a cylindrical manner. At least one section formed in a helix-shaped manner can preferably be formed in a cylinder jacket surface of the module housing. A groove-like depression is synonymously referred to as “groove”.

A section formed in a helix-shaped manner can have at least one groove, which extends over at least a portion of an outer circumference of the module housing.

A section formed in a helix-shaped manner can preferably have at least one groove, which is formed continuously and which completely circles the module housing at least once, preferably twice or several times, on the outside. The individual windings of the groove-like depression are preferably separated from one another by means of a respective, e.g., convex, elevation.

A section formed in a helix-shaped manner can preferably be formed so that a starting region of a groove and an end region of the same groove are offset from each other based on a longitudinal direction of the actuator module and/or of the module housing.

Unlike in the case of a fold-like bellows known from practice with elevations winding azimuthally at a consistent height or point, respectively, in the axial direction or depressions (without gradient or run, respectively, with respect to the axial direction), this means that the convex elevations and concave depressions of the wave contour lying therebetween and alternating in the axial direction do not only run in a circumferential direction or azimuthal direction, respectively, perpendicular to the axial direction but simultaneously in a circumferential direction and also in an axial direction of the module housing, in particular of the module housing wall. To evenly cool such a fold-like bellows with azimuthally running grooves, which alternate in the axial direction with azimuthal elevations, i.e., the cylinder surface of which has a meandering surface shape, represents a challenge and is problematic: in order to achieve an even cooling over the entire axial length, thus all grooves and elevations, a targeted supply and discharge of the cooling medium has to be applied to each individual groove or meandering depression, respectively. To ensure thereby that all meandering depressions or grooves, respectively, are in fact flown around evenly and that, in the worst case, the rest is without cooling, so-called throttle bores are additionally introduced. However, such throttle bores have the disadvantage that they increase the flow resistance, so that more pressure has to be used sometimes than without throttle bores. In addition, it is mechanically complex to achieve the currently required “individual meandering cooling” because very small (nozzle) bores are required as throttles and an, e.g., large-volume supply and discharge of the cooling medium has to therefore be introduced over a very long axial bore through the housing along the fold-like bellows for supply purposes. This is also a cost factor because in particular very long bores are difficult to manufacture in series and because, combined with many small cross bores as (nozzle) bores, this also represents a certain manufacturing risk (e.g., breaking drills, etc.).

The alternating elevations and depressions of the present module housing wall preferably extend with constant gradient proportionately in the azimuthal as well as axial direction, in sum thus in a helix-shaped manner, around the module housing wall, in particular around the jacket surface of the module housing. The flow resistance is thus significantly smaller because the cooling medium flow propagates or flows, respectively, consistently and evenly along the helix, so that a high flow speed can be reached with less pressure, which flow speed is important for an effective cooling. In addition, throttle bores are not required. In the simples case (with a bellows with a continuous helix, which will be explained further below, essentially from an end region in the axial region to the other opposite end region), an inlet and an outlet is sufficient, on which the cooling medium can be let in at the one (e.g. at an end region of the helix) and can be let out at the other (e.g., at the opposite end region of the helix) after passing the entire helix, whereby the entire helix can be evenly cooled very effectively.

The reliability of a piezo actuator can advantageously be improved by means of the actuator module according to the invention because the piezo actuator is effectively protected during operation against damaging environmental influences via the hermetically sealed module housing, in particular against (air) moisture. By means of the combination with the potting compound in the module housing interior space between the piezo actuator and the module housing wall, it is furthermore not only possible to electrically insulate the module housing wall from the piezo actuator but heat can simultaneously also be efficiently guided outwards in or to the module housing wall, respectively, and can be dissipated particularly efficiently from there by means of the wave contour, which is formed in a helix-shaped manner at least in one section, of the bellows of the module housing wall by being flown around with a cooling medium—as will be mentioned further below. The piezo actuator can thus be reliably protected against an overheating. On the one hand, this, in turn, can have an advantageous effect on the service life of the piezo actuator itself, so that the latter or the actuator module, respectively, has to be replaced less frequently. On the other hand, a particularly high metering precision can be attained by means of the actuator module in the case of metering systems because a thermally induced position change of the at least one piezo actuator is largely prevented. The efficiency of a metering system can thus also be improved because the piezo actuator is protected against an overheating even during continuous operation, so that interruptions of the metering operation due to a critical piezo actuator temperature can be avoided.

The actuator module according to the invention is further advantageously also suitable for applications, in the case of which particularly high clock frequencies of a piezo actuator are required because a particularly efficient dissipation of lost heat from a piezo actuator surface to the housing wall takes place via the potting compound in the module housing interior space between the piezo actuator and the module housing wall and a particularly effective output of the heat to the environment is possible via the section, which is formed in a helix-shaped manner, of the wave contour of the module housing wall. The actuator module can thus advantageously be used in jet valves with a very high clock frequency of, e.g., up to 2 kHz, which corresponds to at least a doubling of the clock frequency compared to conventional jet valves and which is not readily possible with known actuator modules. The actuator module could furthermore also be operated successfully in jet valves, which operate with clock frequencies of 3 kHz or 4 KHz.

A metering system according to the invention for a metering substance comprises a nozzle for outputting metering substance, a supply channel for metering substance, an ejection element and at least one such actuator module described above, which is coupled to the ejection element. For the metering substance output, the actuator module can cooperate with the ejection element and/or with the nozzle during operation.

The metering system further comprises a system housing, hereinafter in short referred to only as “housing”, with at least one cylindrical recess in a housing section, e.g., otherwise consisting of solid material, into which recess the actuator module is inserted, preferably so as to fit accurately, during a metering operation. The actuator module can preferably be braced on the head side via a bracing spring in the housing and on the front side against a transmission lever, which transmission lever, in turn, can be braced, for instance, against an ejection element. “So as to fit accurately” is to be understood so that the inner dimensions of the recess and/or the outer dimensions of the actuator module are selected or dimensioned, respectively, so exactly that no free space is present between the two components, if possible. That is, the actuator module is preferably inserted so as to fit accurately, except for a small gap, into the metering system so that an expansion movement of the actuator module can still take place in the recess during operation, without the bellows being able to jam in the recess of the housing. The actuator module and/or the cylindrical recess can in particular be designed and/or adapted to one another so that a cooling medium, which is supplied to a (respective) groove, is largely guided through this groove by means of a cooperation of the elevations delimiting the groove and the housing wall of the recess, i.e., at least a majority of the supplied volume passes through the groove and only a small portion, preferably less than 10%, of the cooling medium flows or jumps over, respectively, the elevations delimiting the groove essentially perpendicular to the direction of extension of the groove.

In order to completely avoid a flow-over or jump-over, respectively, as a result of a small distance between the elevations of the bellows and the recess of the housing of the metering system, the actuator module can preferably be provided with a tubular sheath for the metering operation, which is particularly preferably pulled onto or around the actuator module, respectively, so as to fit accurately or with which the actuator module is surrounded, respectively. Such a sheath can comprise at least two openings, thus, e.g., an inlet and an outlet opening, in its material surface, i.e., be provided with at least two holes. Apart from that, the sheath can encase the actuator module on the other side during a metering operation in a metering system. Cooling medium can be let into the groove of the actuator module, which is sheathed by means of the sheath, i.e., cased radially on the outside, through the openings and can be let out again at the end of the groove.

The sheath is, for example, a rubber sleeve, which is elastic, i.e., stretchy/expandable and which is temperature-resistant based on the common operating temperatures, or the like, which can yield elastically to a certain expansion movement of the actuator module.

The sheath can preferably form a hermetic seal, which is tight on the other side, of the grooves of the bellows of the actuator module radially outwards with respect to the surrounding housing. This makes it possible, for instance, that the recess of the housing does not have to ensure the necessary seal on its own in that it is necessarily designed to be so snug or accurately fitting, respectively, that the actuator module just barely fits. On the contrary, the recess in the housing of the metering system can thus also be realized with some play with respect to the actuator module.

Supply hoses, i.e., an insertion hose and a discharge hose, can particularly preferably be connected to the inlet and outlet opening of the sheath. For example, they can also be vulcanized directly during the production and/or attachment of the sheath. For example, bores, which otherwise end in the recess of the housing, e.g., can thus also be forgone for the supply and discharge of the cooling medium by means of longer supply hoses, which are guided out of the recess of the housing, for example.

In the case of several cylindrical recesses in a metering system, one actuator module is preferably in each case inserted for each recess. Several actuator modules lend themselves, for example, when metering is to take place with a particularly high clock frequency.

For cooling purposes, in particular of the actuator module, the housing of the metering system thereby has at least one inlet opening into the recess, for introducing a cooling medium into at least one groove on the outer side of the bellows. The housing of the metering system furthermore has at least one outlet opening from the recess for discharging the cooling medium from at least one groove. After the introduction of cooling medium into a groove at a first point based on the axial direction or based on a position along the wave contour, respectively, the new discharging or discharging, respectively, takes place at a different, later point or at another position long the wave contour, respectively, preferably from the same groove. In the case of a corresponding design of the bellows, the discharge could also take place from another groove, as will be explained further below. The inlet or outlet opening, respectively, is the actual opening, i.e., entry or exit point, respectively, at which the cooling medium is introduced or discharged, respectively, into or out of the groove, respectively, on the outer side of the bellows.

Liquid and/or gaseous media are suitable as cooling medium, whereby cooling media with a high heat capacity are preferred. The cooling medium can thus be a gas, such as helium, for example. The cooling medium can preferably be air. Gas, in particular air, has the advantage that the components, which are flown around, are not contaminated and that a cleaning, etc., does not have to take place even in the case of a possible leak.

Compressed and (actively) cooled-down air can particularly preferably be used as cooling medium, because said air can be provided with relatively little effort and can also be blown into a groove of the bellows through an inlet opening. For example, at least one vortex tube can be realized as cold source in order to cool down the cooling medium to a certain (target) temperature. The cooling medium for the metering system can thus also be operated at unfavorable ambient conditions, such as, e.g., particularly high ambient temperatures, with a maximum metering frequency, whereby a high metering precision is ensured at the same time.

Alternatively or additionally, the cooling medium can also be a liquid, such as, e.g., water, alcohol or oil.

During operation, the bellows is inserted, as mentioned, into the cylindrical recess, which preferably fits accurately. The recess can be, for example, a bore in the housing of the metering system. By introducing the cooling medium into an intermediate space between bellows and recess, i.e., in the case of an accurately fitting recess then (as) completely (as possible) into a depression or groove, respectively, which winds in a spiral-shaped or helix shaped manner, respectively, along the bellows, in the outer contour of the bellows, the cooling medium can be conveyed or guided, respectively, on the outer side of the bellows from an inlet point, e.g., at one end of the bellows, to another outlet point, e.g., at the other end of the bellows. The cooling medium can advantageously be guided through the helix-shaped or spiral-shaped groove, respectively, over a defined distance in the circumferential direction and in the longitudinal direction of the actuator module. By means of a cooperation of at least one groove in the module housing with an inlet opening and an assigned outlet opening, a directed cooling medium flow can be generated, so that the cooling medium flows continuously, in particular evenly, around a certain (partial) section of the actuator module. Regions of the actuator module, which are spaced apart from an inlet opening, can advantageously also be reliably supplied with cooling medium during operation by means of a flow guidance through a groove. A consistent and even cooling of the module housing wall can thus advantageously be achieved with the helix-shaped section. In the case of known encapsulated piezo actuators, in contrast, an application with compressed air, e.g., can have the result that different regions of the piezo actuator are cooled differently.

In the case of the metering system according to the invention, the cooling medium can continuously absorb heat or heat up, respectively, when flowing through the groove(s) due to the contact with the bellows of the module housing wall. The heat, which is generated within the module housing wall on the piezo actuator during operation and which the piezo actuator guides outwards, preferably in the lateral or radial direction, respectively, based on a longitudinal extension of the piezo actuator, into or to the module housing wall, respectively, by means of the heat-conductive potting compound, can be output directly to the outside of the module housing again to the cooling medium, which flows past, via the module housing wall. The module housing wall can preferably also have a high heat conductivity. The heat can thus be discharged or transported away effectively, respectively, on the outer side of the bellows without overheating or heat accumulation, respectively, in a continuous flow. The cooling medium heated up in this way is ultimately discharged or dissipated again, respectively, via the outlet opening in the housing. If desired, it can be supplied or let in, respectively, through the inlet opening again for the renewed cooling, after it has reached its initial temperature again-either by means of active or passive cool-down -by forming a cooling circuit. As a whole, the metering system can thus be effectively held below a provided highest or maximum operating temperature, respectively, even during continuous operation, whereby a temperature of the encapsulated piezo actuator, e.g., a core temperature, is preferably maximally 200° C., preferably maximally 160° C., particularly preferably maximally 140° C. The temperature can preferably maximally be 140° C. at the surface of the piezo actuator. In addition to the components described just now, the metering system can comprise further components, as will be described later.

The actuator module according to the invention can advantageously be used successfully in a metering system, in particular in a jet valve, as has been described above. Compared to known metering systems with conventional encapsulated piezo actuators, in the case of which the surface structure of the encapsulation is furthermore also not designed in a helix-shaped manner even for cooling purposes, a clock frequency of the metering substance output can in particular be increased significantly by using the actuator module with the helix-shaped wave contour according to the invention in a housing encapsulating the piezo actuator and the cooling in the metering system, which is tailored to this.

Further, particularly advantageous designs and further developments of the invention follow from the dependent claims as well as from the following description, whereby the independent claims of one claim category can also be further developed analogously to the dependent claims and exemplary embodiments of a different claim category and individual features of different exemplary embodiments or variations, respectively, can also be combined to form new exemplary embodiments or variations, respectively.

The potting compound can preferably comprise a base compound and an auxiliary substance. The base compound can thereby be a cured, preferably vulcanized and thus elastic substance, in particular after a hardening or curing, respectively, in the module housing interior space of the module housing. For the production of an actuator module, the potting compound is preferably cast into the module housing interior space between the piezo actuator and the module housing wall, in which it then cures after a certain time. For example, the components of the potting compound can be provided outside the module housing, e.g., by mixing the base compound and the auxiliary substance, and can then be introduced into the module housing in the form of a free-flowing compound (potting compound). The base compound can cure in the module housing interior space in order to form the operational (hardened) potting compound.

The at least one auxiliary substance can at least be particulate, heat conductive and dielectric. In particular, the auxiliary substance itself is a dielectric. The fact that the auxiliary substance is formed to be particulate means that the auxiliary substance is present as a solid at least in the base compound of the potting compound, preferably also in the hardened potting compound. For example, the auxiliary substance can comprise a plurality of individual auxiliary substance particles or auxiliary substance particulates, respectively, auxiliary substance platelets or the like. An “auxiliary substance platelet” is understood to be a flat element or particle, respectively, which has essentially the same thickness throughout and which is delimited on two opposite sides by a respective predominantly flat surface (base surface), which is comparatively expanded compared to a thickness. It should be pointed out that a respective auxiliary substance particle can also be designed only approximately as “auxiliary substance platelet”. Those auxiliary substance particles, which have slightly different thicknesses within the same particle, are accordingly also referred to as “auxiliary substance platelets”. The base surfaces can have different geometries, such as, e.g., approximately elliptical or circular shapes, wherein an outer contour of a base surface can also be formed irregularly. A “platelet-like” auxiliary substance particle, also referred to as auxiliary substance platelet, is accordingly defined in particular in that it has two predominantly flat base surfaces, wherein a thickness of the auxiliary substance particle (corresponds to the distance between the base surfaces) is several times smaller in relation to the expansion of the base surfaces.

The potting compound can generally comprise two or more different types of auxiliary substances, e.g., different auxiliary substance particles.

The auxiliary substance can thereby preferably be arranged in the potting compound in the module housing, preferably also in the base compound in the housing, so that a heat dissipation from the piezo actuator, more precisely the piezo actuator surfaces, to the module housing wall takes place during operation of the actuator module via the potting compound, in particular via the auxiliary substance in the potting compound.

An inherent heat conductivity of the auxiliary substance, i.e., a heat conductivity of the auxiliary substance itself, can preferably be at least approximately 2.5 W/(m·K), preferably at least approximately 30 W/(m·K), preferably at least approximately 50 W/(m·K), more preferably at least approximately 100 W/(m·K), more preferably at least approximately 200 W/(m·K), particularly preferably at least approximately 300 W/(m·K), in particular at least approximately 400 W/(m·K). The above-mentioned values can preferably refer to the heat conductivity of an auxiliary substance, which is present in the form of a solid material block, e.g., a massive auxiliary substance block. As is customary, the heat conductivity or the heat conduction coefficient, respectively, is understood to be a substance property of the auxiliary substance, which determines the flow of heat through a material or the auxiliary substance, respectively, due to the heat conduction.

A powdery auxiliary substance, in particular (still) outside the potting compound, can preferably have an (inherent) heat conductivity of at least approximately 1 W/(m·K), preferably at least approximately 2 W/(m·K), preferably at least approximately 3 W/(m·K), more preferably at least approximately 4 W/(m·K), more preferably at least approximately 5 W/(m·K). The powdery auxiliary substance can preferably be boron nitride and/or comprise boron nitride.

The heat conductivity of the base compound (without auxiliary substance), e.g., a silicone gel, is preferably at least 0.08 W/(m·K), preferably at least 0.15 W/(m·K), in particular at least 0.2 W/(m·K).

The heat dissipation can take place with the heat-conducting, dielectric auxiliary substance arranged in the potting compound during operation of the actuator module in particular from a surface of the piezo actuator essentially evenly along a total longitudinal extension of the piezo actuator, in particular in a lateral direction. The heat dissipated by the piezo actuator can preferably be transmitted largely to a module housing jacket of a module housing wall via the potting compound, as will be described later. The auxiliary substance, in particular the auxiliary substance particles or auxiliary substance platelets, can preferably largely be arranged so that a longitudinal extension of a respective auxiliary substance particle or auxiliary substance platelet, respectively, runs transversely, preferably essentially orthogonally, to a longitudinal extension of the piezo actuator in the module housing. Particularly preferably, the auxiliary substance particles or auxiliary substance platelets, respectively, can be arranged in the potting compound so that their longitudinal extension corresponds to a shortest distance between a piezo actuator surface and the module housing wall.

The longitudinal extension (longitudinal expansion) of the piezo actuator is understood to be the largest or longest extension (expansion), respectively, of the piezo actuator in one direction. The longitudinal extension of the piezo actuator is preferably parallel to the axial direction of the module housing. The longitudinal extension (longitudinal expansion) of an auxiliary substance platelet is understood to be the largest or longest extension (expansion), respectively, of the auxiliary substance platelet in one direction, in particular along at least one base surface of the auxiliary substance platelet.

A particularly efficient heat dissipation during operation can advantageously take place via the particular arrangement of the auxiliary substance platelets in the base compound or in the potting compound, respectively, with respect to the piezo actuator. In the case of piezo actuators, a heat emission usually takes place largely in the lateral or radial direction, respectively, due to the layered construction during operation. This means that lost heat is output predominantly towards the side away from a piezo actuator surface with regard to the longitudinal extension of the piezo actuator, wherein heat is hardly output in the axial direction, e.g., in the direction of an actuator front or actuator end, respectively. In the case of encapsulated piezo actuators, it is thus particularly effective when at least a majority of the lost heat can be fed laterally or radially, respectively, away from the piezo actuator via the auxiliary substance platelets in the potting compound, in particular because a lateral region of a piezo actuator accounts for a relatively large portion of a total surface of the piezo actuator.

In combination with the features, which have already been mentioned above, for instance relating to the at least one helix-shaped section of the wave contour of the module housing wall, the heat, which the piezo actuator guides into the module housing wall during operation, can be dissipated effectively from the metering system by the actuator module and a heat dissipation can thus additionally be improved even further as a whole.

The base compound of the potting compound can preferably comprise a silicone, in particular a silicone gel, preferably for providing a cured or curable substance, respectively. The silicone gel can preferably comprise at least one base silicone and a crosslinking agent. The base silicone can be, e.g., a silicone of the type SG 75L2-30, whereby a type SG 79L5-30 can be used as cross-linker (manufacturer in each case: Elantas, Germany).

Alternatively, at least one polyurethane or another suitable silicone could also be used instead of silicone, wherein the base components of the base compound should preferably have at least the above-mentioned insulation and heat conductivity values.

The auxiliary substance can preferably be boron nitride (BN). Particularly preferably, the auxiliary substance can be hexagonal boron nitride (α-boron nitride). Hexagonal boron nitride (α-Bn, hexagonal) consists of layers of a planar, hexagonal honeycomb structure, in the case of which the B- and N-atoms in each case appear alternately and is moreover well known. Particularly preferably, the boron nitride can be present as auxiliary substance prior to the processing in powder form with a pronounced crystal structure. Prior to the processing and/or in the hardened potting compound, the boron nitride can in particular be present in the form of platelet-shaped single crystals. Particularly preferably, a respective (BN) single crystal can in each case form an auxiliary substance particle or in each case an auxiliary substance platelet, respectively. In particular a combination of boron nitride with the curable base compound ensures a particularly effective heat dissipation, e.g., when they are cast jointly in the module housing interior space and the boron nitride is aligned or oriented, respectively, in a suitable manner with its longitudinal extension in the direction to the nearest module housing wall section prior to curing the silicone.

In the axial direction, the helix-shaped section can preferably in each case start at a distance, i.e., spaced apart, from a respective front side of the module housing and can in each case extend from there in the axial direction to the other front side at least in sections, in particular extend in the direction of an opposite front side. Particularly preferably, the respective helix-shaped section can extend at least to the center of the bellows (based on the axial direction of the module housing). A first front side of the module housing can preferably comprise a base surface of the cylinder-like module housing, can in particular be formed thereby. A second front side of the module housing can preferably comprise an opposite cover surface of the cylinder-like module housing, in particular be formed thereby.

In a respective end region close to the respective front side, the module housing wall of the module housing can in each case preferably have flat or smooth sections, respectively, i.e., which taper off freely, in each case adjacent to the helix-shaped section on the end side. This means that the bellows tapers off freely in sections on the two ends, thus in a region close to an axial front side of the module housing or is formed to taper off freely, i.e., smoothly, respectively. The inlet opening as well as the outlet opening can thus be arranged at any azimuthal position or contact surface, respectively, to the bellows in front of an end section or end region thereof, respectively, in the recess of the metering system. The exact alignment of the bellows, thus how it is positioned in the recess in the metering system so as to be rotated about its axis of rotation, can thus also be less important under normal circumstances, i.e., it can be arranged in the recess of the housing of the metering system so as to be rotated about its longitudinal axis in this respect, insofar as its electrical terminals do not specify a specific alignment.

There are different options for the shape and design of the wave contour or helix, respectively. For example, the bellows can generally have a continuous helix (in other words, a cylindrical spiral or a thread, respectively), thus have a clockwise or counter-clockwise thread or a right-handed or left-handed helix, respectively, e.g., continuously essentially over its entire longitudinal extension. The helix-shaped section can preferably have at least one thread spiral. The thread spiral is preferably formed by the housing wall.

In the axial direction, the bellows can preferably have at least two helix-shaped sections running in opposite directions. For example, the bellows can have two helix-shaped sections, each with a groove, wherein the grooves are formed so as to run in opposite directions. Running in opposite directions means hereby that the sections, e.g., the grooves, have a different winding direction, sometimes also referred to as mobility or helical direction. In the case of two helix-shaped sections running in opposite directions, one section thus has a right-handed thread and the other accordingly a left-handed thread. The bellows can preferably have two thread spirals with different helical direction.

In the installed state of the actuator module in the metering system, this makes it possible that the cooling medium is conveyed via the helixes of the bellows to the ends of the bellows in equal shares, in particular provided that an inlet opening for cooling medium is assigned to a central region of the bellows, wherein half of the generated heat can thus be conveniently discharged. It is thus particularly advantageous that at the point where a piezo actuator typically has the highest heat-up, namely at mid-length, i.e., in the center, freshly cooled cooling medium is applied to the actuator module, e.g., with a (target) starting temperature, and the actuator module is thus cooled particularly strongly there, wherein the cooling power optionally decreases slightly towards the two ends (at which the piezo actuator is typically also heated up less strongly). Such a bellows would thus ideally be adapted to the heat dissipation or lost heat profile, respectively, of the piezo actuator.

Regardless of this, however, the two helix-shaped sections with an opposing winding direction still have a further advantage. That is to say, they prevent that the bellows could possibly unintentionally rotate, deform or twist, respectively, over time during operation due to torsional forces at a high operating load due to a wave contour, which is formed continuously in a winding direction, whereby a precise metering operation would then not be possible any longer. In the case of two sections running in opposite directions, compared to a continuous or uniform section, respectively, half a torsional moment is generated in each of the two sections. However, the two generated torsional moments do not add up to the above-mentioned whole torsional moment, but they cancel each other out at least largely or completely due to the opposing winding direction and associated opposing direction of action or direction of rotation, respectively.

At least two of the helix-shaped sections, particularly preferably with opposing winding direction, can preferably be separated from one another. In this case, the cooling medium can be discharged again from a different groove than from that groove, into which it was introduced initially. The introduction could thus take place into a first groove, which is separated from or interrupted by, respectively, the second groove, from which the cooling medium is then discharged again, by means of a groove-free jacket section.

The at least two, preferably separate, helix-shaped sections can preferably be separated from one another by means of a flat or smooth section, respectively. The flat section is preferably formed by the module housing wall. The two helix-shaped sections can generally have the same winding direction. It is preferred, however, that the two helix-shaped sections have an opposing winding direction. Accordingly, the two helix-shaped sections can preferably in each case have a thread spiral with a different helical direction.

Started at the flat section, the helix-shaped sections can preferably in each case extend in the axial direction to the ends or front sides, respectively, of the module housing. This can be advantageous when several inlet openings and/or outlet openings are provided in the housing of the metering system.

The flat section can particularly preferably be arranged in the center of the bellows and two helix-shaped sections can each extend outwards from there to the two opposite ends of the bellows, in particular in each case in the direction of a front side of the module housing. Cooling medium could then be introduced through inlet openings thereby, for example at the two ends, e.g., in each case in the vicinity of the front sides, and could be discharged in the center through an outlet opening or, as preferred, vice versa, i.e., that the cooling medium is introduced into the recess in the metering system at the height of the center of the bellows and is let out or discharged again, respectively, at the height of the two ends of the bellows.

For the secure sealing between the outer surface of the bellows and the inner surface of the recess of the housing of the metering system (e.g., if the components are not adapted to one another so as to fit accurately or in a supporting manner), a ring-shaped sealing element, such as, e.g., an O ring, can be arranged at least in the region of one end of the bellows. In the case of such a sealing element at the respective end of the bellows, the cooling medium always remains in a region between or within the sealing elements, respectively, when it is introduced within said region, so that there is no risk that the cooling medium reaches into other regions of the metering system, thus, e.g., exits unintentionally at the walls along the recess or at the bellows, respectively, from the housing on the top or—if not desired—unintentionally penetrates into the region of a lever and/or ejection element on the bottom.

A respective sealing element contact section of the inner surface of the recess, at which the respective sealing element seals the bellows radially on the inner side and the recess radially on the outer side with contact, can preferably directly adjoin the inlet and/or outlet openings. This has the advantage that a dead center, at which cooling medium could otherwise possibly build up or accumulate, respectively, when the cooling medium is let in or let out slightly at a distance therefrom, is not created at the sealing element itself.

There are different options for the design of the wave contour, in particular of the elevations and depressions, e.g., of the groove-like depression.

At least one of the helix-shaped sections of the bellows can preferably have a gradient of preferably at least 1 mm, particularly preferably at least 5 mm, most preferably at least 10 mm.

Alternatively or additionally, at least one of the helix-shaped sections of the bellows can have a gradient of preferably maximally 35 mm, preferably maximally 20 mm, particularly preferably maximally 15 mm. At least one groove of a helix-shaped section can preferably have an afore-mentioned gradient. The term “gradient” refers to the same gradient here as it is used and specified accordingly in the case of a screw thread.

There are also different options for the design of the metering system, in particular of the recess.

The recess of the metering system can preferably have at least one radial inlet opening.

Alternatively or additionally, the recess of the metering system can have at least one radial outlet opening. The respective inlet or outlet opening, respectively, can in particular be arranged radially with respect to the cylindrical recess in the housing. The respective radial inlet or outlet opening, respectively, can preferably be formed essentially orthogonally with respect to a longitudinal extension or longitudinal direction, respectively, of a mounted housing module, in particular transversely to the axial direction of the housing module.

In the case of an actuator module, which is installed in the metering system, with module housing, the radial inlet opening and/or the radial outlet opening can particularly preferably be located essentially at a height of an upper end section of the module housing. The upper end section can preferably face away from an ejection direction of the metering substance from the metering system.

Alternatively or additionally, the radial inlet opening and/or the radial outlet opening can be located at a height of a lower end section of the module housing. The lower end section can preferably face an ejection direction of the metering substance from the metering system.

At least one of the walls, which axially delimits, thus at least partially axially delimits, the recess of the housing, can have an inlet opening or an outlet opening. An axial delimiting of the housing preferably refers to the axial direction of the installed module housing, i.e., a delimiting towards the front sides of the module housing.

Alternatively, one of the walls, which axially delimits the recess of the housing, can preferably have an inlet opening, and the other, opposite wall can have an outlet opening. In a region close to an axial front side or front surface, respectively, of the module housing, the cooling medium can thus be introduced into a groove of the bellows from an axial direction, e.g., approximately parallel to a longitudinal extension of the module housing, and, in a region close to the opposite other, axial front side or front surface, respectively, of the module housing, it can be discharged from a groove of the bellows. This embodiment has the particular advantage that the entire cooling with supply and discharge of the cooling medium can be accommodated on the installation space of the cross sectional surface of the actuator module, i.e., in the axial extension of the piezo actuator, and a corresponding metering system or metering valve, respectively, can thus be embodied in a highly space-saving manner, which is a large advantage especially in the case of parallel applications, thus, for example, with metering units with several metering systems, which are arranged in parallel, because the metering systems can be arranged close to each other and the nozzles thus lie very close to each other.

It should be mentioned at this point that it is also possible that the recess is formed to be widened radially (at least over certain sections) around the region of the end section of the bellows, so that the cooling medium can be introduced into the groove on the outer side of the bellows from an axial direction past the end section of the bellows through the widened section(s) of the recess, as will be explained in more detail further below on the basis of an exemplary embodiment.

In the case of an actuator module, which is installed as intended, the recess in the metering system can preferably have an inlet opening in the center, thus viewed in the axial direction of the module housing, at a center plane, between the front sides of the module housing of the actuator module in a radial wall, for introducing the cooling medium, e.g., from a radial direction, into the recess. The cooling medium can preferably be introduced so that cooling medium is applied to the surface of the bellows. The radial wall of the recess preferably faces the bellows and/or extends parallel to the longitudinal direction of the module housing.

In the case of a metering system with a transmission mechanism, which is arranged in a further recess between the piezo actuator and the ejection element, an outlet opening can preferably be arranged in the region of the transmission mechanism. The outlet opening in the region of the transmission mechanism provides for a flow-through or flow-around, respectively, of the components of the transmission mechanism, such as, for example, the transmission lever, so that abrasion, which may be generated there during operation, can be transported away directly and the components can simultaneously be cooled at least slightly.

Alternatively or additionally, an outlet opening can be arranged in the region of the ejection element. This additionally provides for a cooling and cleaning at least of portions of the ejection element.

Again alternatively or additionally, at least one inlet opening can be formed at an axial end region of the bellows, preferably in the region of an, e.g., upper front side of the module housing, for introducing the cooling medium, which, again, provides for instance for a highly space-saving design of the metering system. Starting from one end of the bellows, in particular from the one end of the module housing, the entire actuator module can additionally be cooled all the way to the transmission mechanism in the region of the ejection element in this way and, as already mentioned, material abrasion created during operation can be blown or flushed out of the transmission mechanism, respectively. It can then lend itself hereby to post-treat, to clean or the filter the cooling medium accordingly, when it is to be used again subsequently after the cool-down, which is considered to be desirably in terms of sustainability.

At an axial end region of the bellows, the inlet opening can particularly preferably be formed for introducing the cooling medium from an axial direction. A particularly compact arrangement of housing, cooling medium supply and actuator module can thus be attained because a lateral supply bore and/or terminals are not required and the lateral installation space requirement of the metering system is thus reduced. This is advantageous in particular when a high packing density of several metering systems, which are arranged close together, is required or desired. An inflow direction of the cooling medium can preferably be parallel to a longitudinal direction of the module housing. For example, an axially running bore in the form of a recess at the edge of an upper front side of the module housing or in the form of a recess can be formed by a cover plate of the module bousing along an outer side of the module housing wall to the bellows on the actuator module.

Particularly preferably in the case of a metering system with an inlet opening at an end region of the bellows at the end side of the piezo actuator, the housing can preferably have a further recess, which particularly preferably extends transversely thereto, on the front side of the piezo actuator. The further recess can connect to the piezo actuator and/or to the recess for the actuator module, for example in an ejection direction (of the metering substance). A transmission lever, which transmits the longitudinal expansion of the piezo actuator, in particular a change of the longitudinal expansion, via a lever arm of the transmission lever to the ejection element of a resiliently mounted tappet device, can thereby be arranged in the further recess. The transmission elver can be asymmetrical, for example.

The tappet device typically protrudes with the ejection element into a nozzle of a fluidic unit of the metering system, which nozzle is supplied with a metering medium by means of the fluidic unit.

The outlet opening for the cooling medium can thereby preferably be arranged in the region of the further recess close to the resiliently mounted tappet device. The cooling medium, which is introduced at the end side of the piezo actuator at an inlet opening of the housing at the end region of the bellows, e.g., in the region of a front side facing away from the ejection direction, can thus flow through and cool the entire metering system, in particular the actuator module, including the further recess.

The invention will be described once again in more detail below with reference to the enclosed figures on the basis of exemplary embodiments. Identical components in the different figures are thereby provided with identical reference numerals. The figures are to be understood only schematically here and are also not true-to-scale, in which:

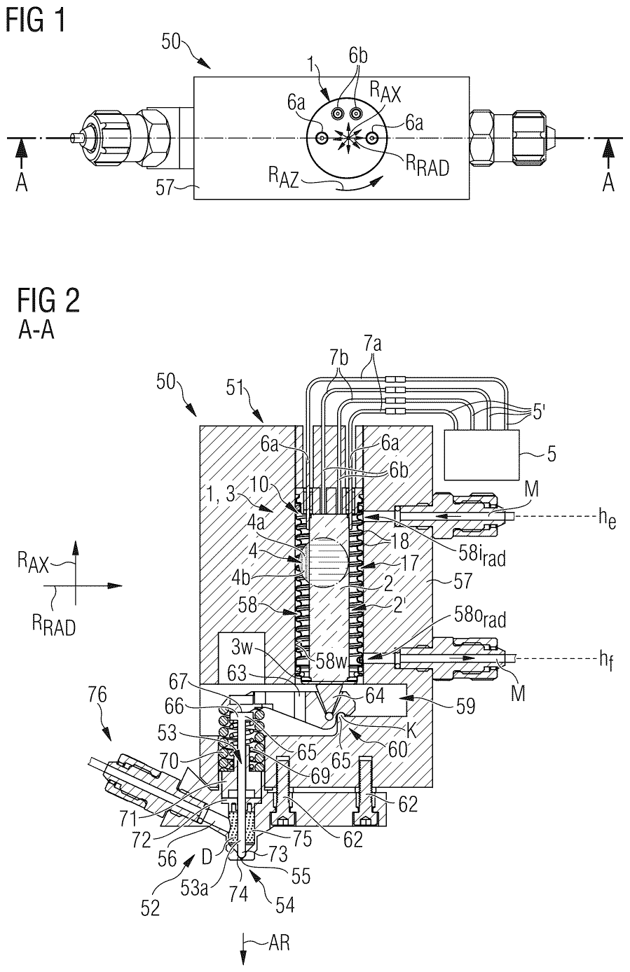

FIG. 1 shows a roughly schematic cross sectional illustration through an exemplary embodiment of a metering system according to the invention with an installed actuator module according to the invention,

FIG. 2 shows a roughly schematic sectional illustration along a section line A-A through the metering system from FIG. 1,

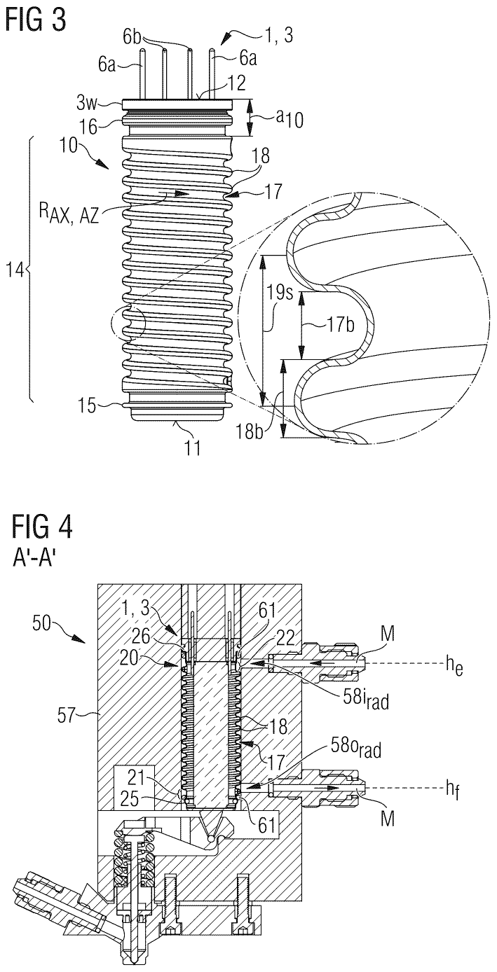

FIG. 3 shows an isolated, lateral view of the actuator module from FIG. 1 and FIG. 2,

FIG. 4 shows a roughly schematic sectional illustration of parts of the metering system from FIG. 2 with a slightly modified variation of the installed actuator module, according to an analogous section line A′-A′ through the metering system,

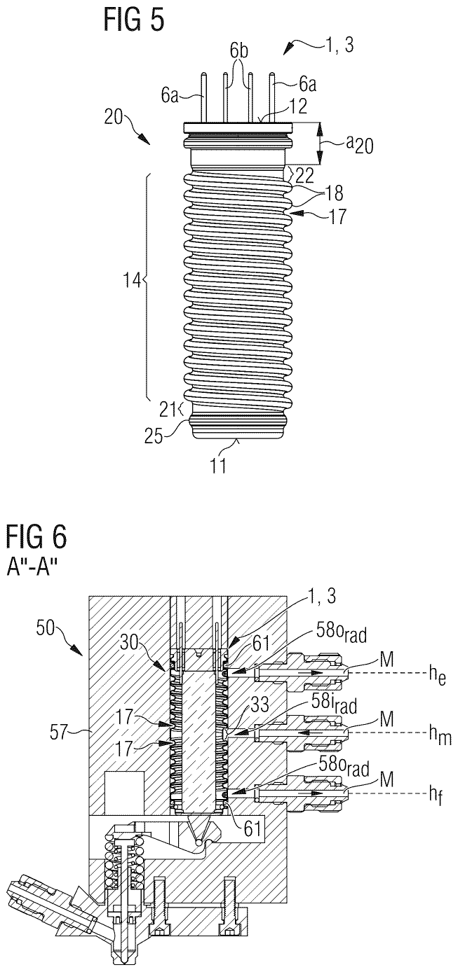

FIG. 5 shows an isolated, lateral view of an actuator module from FIG. 4, which is slightly modified compared to the actuator module from FIG. 3,

FIG. 6 shows a roughly schematic sectional illustration of parts of an exemplary embodiment of a metering system according to the invention with an actuator module according to the invention according to an analogous section line A″-A″ through the metering system,

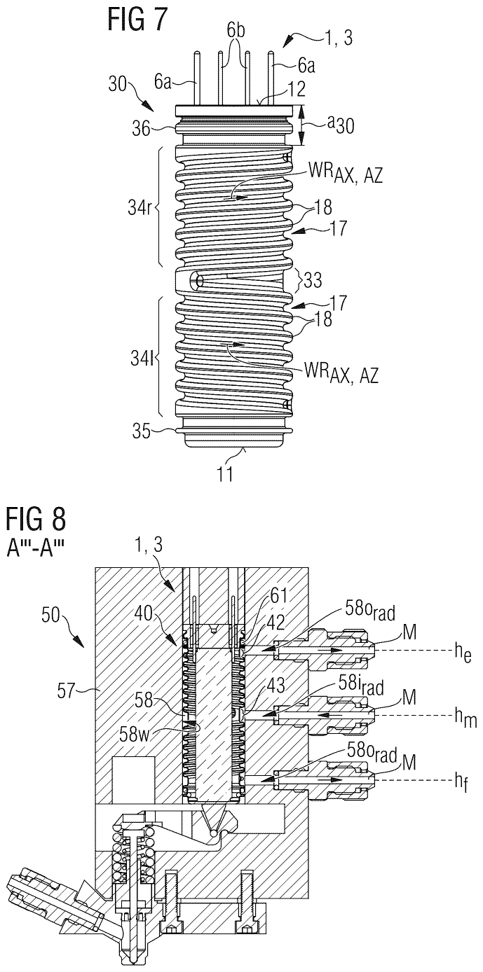

FIG. 7 shows an isolated, lateral view of the actuator module from FIG. 6,

FIG. 8 shows a roughly schematic sectional illustration of a variation of the metering system from FIG. 6, which is adapted to a slightly modified variation of the installed actuator module, along an analogous cutting line A″-A″ through the metering system,

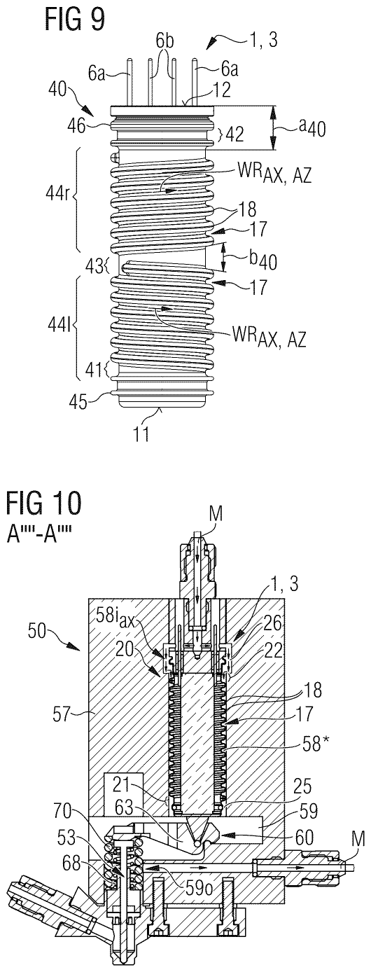

FIG. 9 shows an isolated, lateral view of an actuator module from FIG. 8, which is slightly modified compared to the actuator module from FIG. 6,

FIG. 10 shows a roughly schematic sectional illustration of parts of an exemplary embodiment of a metering system according to the invention with the actuator module from FIG. 4, according to an analogous section line A″″-A″″ through the metering system,

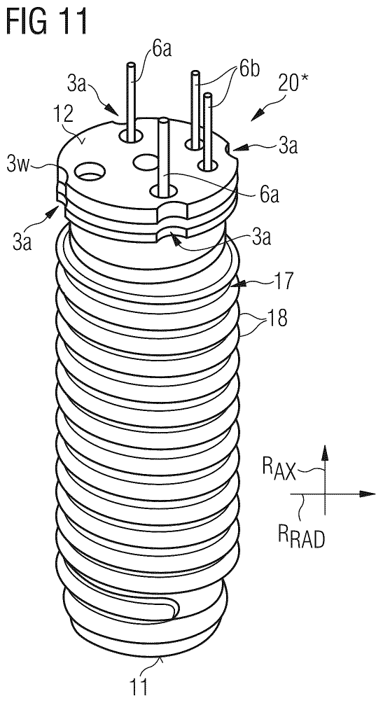

FIG. 11 shows an isolated, lateral view of an actuator module, which is slightly modified compared to the actuator module from FIG. 10,

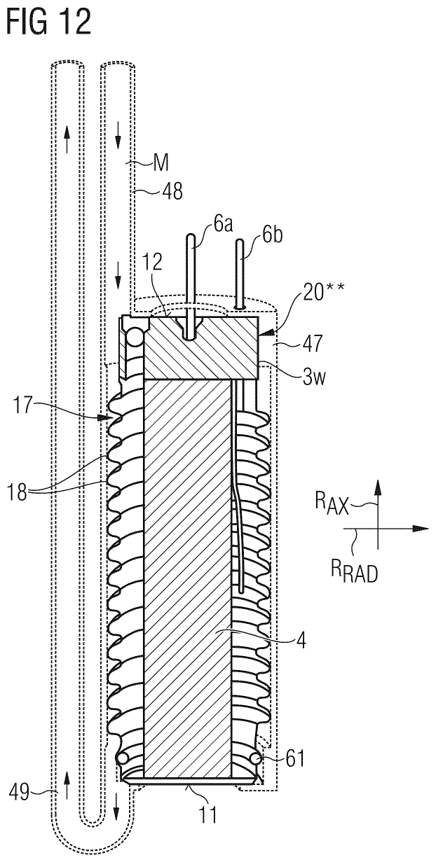

FIG. 12 shows a roughly schematic sectional illustration of a further actuator module, encased in an expandable, tight sheath, which comprises a supply hose as well as a discharge hose for cooling medium,

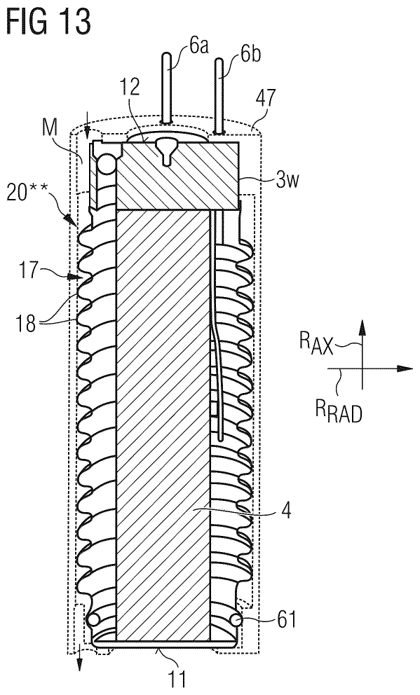

FIG. 13 shows a roughly schematic sectional illustration of the actuator module from FIG. 12, this time with a sheath without supply as well as discharge hose.

As mentioned, the above-described actuator module can be used, for example, in a metering system for metering liquid to viscous metering substances, e.g., in a jet valve, which is shown purely schematically and in section in FIG. 2. Due to the fact that the basic setup of jet valves of this type is known, only the essential elements will be described below.

As essential components, the metering system 50, which is shown in a cross section in FIG. 1 and in a longitudinal section in FIG. 2, comprises an actuator assembly 51 as well as a fluidic assembly 52, which is releasably coupled thereto, wherein the coupling takes place here in an exemplary manner via two screws 62. The actuator assembly 51 essentially comprises all components, which ensure the drive or the movement, respectively, of an ejection element 53a or of a tappet 53a, respectively, of a tappet device 53 of the fluidic assembly 52 in a nozzle 54.

In addition to the nozzle 54 and a supply channel 56 for metering substance D to the nozzle 54, the fluidic assembly 52 comprises all further parts, which are directly in contact with the metering substance D, as well as additionally the elements required to assemble the respective parts, which are in contact with the metering substance D or metering medium D, respectively, or to hold them in their position on the fluidic assembly 52, respectively.

In the exemplary embodiment of the metering system 50 shown in FIG. 2 here (as well as in the further, shown exemplary embodiments), the actuator assembly 51 comprises a housing 57, more precisely a housing block 57, with two internal chambers 58, 59, namely on the one hand, an actuator chamber 58 with an actuator module 1 located therein with at least one piezoceramic actuator 2, which is hermetically encapsulated into a module housing 3 (FIG. 2), and, on the other hand, an action chamber 59, into which a movable ejection element 53a, here a tappet 53a, of the fluidic assembly 52 protrudes. Via a transmission mechanism 60 comprising a lever 63, which extends from a region in the action chamber 59 below the actuator chamber 58 essentially horizontally into a region of the action chamber 59 above the tappet device 53, the tappet 53a is actuated by means of the actuator module 1 so that the metering substance D to be metered is ejected from the fluidic assembly 52 in the desired quantity at the desired point in time via the nozzle 54 in an ejection direction AR. The tappet 53a seals a nozzle opening 55 and thus also serves as sealing element 53a. Due to the fact, however, that the largest portion of the medium is ejected from the nozzle opening 54 by means of the tappet 53a only when the tappet 53a moves towards the nozzle opening 55 in the ejection direction AR, it is referred to here as ejection element 53a.

In order to control the piezo actuator 2 (FIG. 2), the actuator module 1 is connected electrically or in terms of signals, respectively, to a control means 5, which can also be formed, e.g., as part of the metering system 50. The connection to the control means 5 takes place via connection cables 5′, which are connected on the end side to actuator module control terminals 7a, e.g., suitable plugs 7a.

The actuator module control terminals 7a in each case contact an electrical terminal 6a in the module housing 3, here two contact pins 6a, which are each fed through a module housing wall 3w of the module housing 3 in a hermetically tight and electrically insulated manner. In FIG. 1, the actuator module 1 comprises a total of four contact pins 6a, 6b, which are arranged in a front side 12 or end side 12, respectively—which can also be referred to as module housing cover—of the module housing 3 (see FIG. 3). The two outer contact pins 6a here serve the purpose of controlling the piezo actuator 2 or for the communication between piezo actuator 2 and control means 5, respectively.

The two contact pins 6b shown centrally here are used in order to transmit measuring values from temperature sensors from the module housing 3 to the control means 5. For this purpose, the contact pins 6b are in each case connected on the one side to the control means 5 via temperature sensor terminals 7b via connection cables 5′ and on the other side to the individual temperature sensors (not shown here) in the module housing 3. For example, measuring values from several temperature sensors could also be transmitted to the control means 5 in a spatially resolved manner via the contact pins 6b.

The piezo actuator 2 (FIG. 2) arranged in the module housing 3—and via this also the module housing 3—can expand and contract again in the longitudinal direction of the actuator chamber 58 according to a connection by means of the control means 5. The actuator module 1 can be placed into the actuator chamber 58 from the top and can be mounted therein in a height-adjustable manner, wherein an exact adjustment of the actuator module 1 with regard to a movement mechanism is made possible by means of a transmission mechanism 60. In the case shown here, the module housing cover or the end side 12, respectively (FIG. 3) supports itself on the inside of the actuator chamber 58 via a support element, which is not shown in detail, wherein the support element serves as upper abutment here and can be adjusted, e.g., by means of a screwing movement (not shown) for an adjustment of the actuator module 1. The actuator module 1 is accordingly mounted here on the bottom on the lever 63 via a pressure piece 64, which tapers downwards at an acute angle, which lever, in turn, rests on a lever bearing 65. The lever 63 can be tilted about a tilt axis K via this lever bearing 65, so that a lever arm of the lever 63 reaches through the action chamber 59. On the end of the lever arm, the latter has a contact surface 66, which points in the direction of the tappet 53a of the fluidic assembly 52 coupled to the actuator assembly 51 and which pushes onto the contact surface 67 of the tappet head 68.

In the case of all of the shown exemplary embodiments, it is provided that the contact surface 66 of the lever 63 is permanently in contact with the contact surface 67 of the tappet head 68, in that a tappet spring 69 presses the tappet head 68 against the lever 63 from below. It would generally also be possible, however, that in an initial or rest position, respectively, of the tappet spring 69, a distance between tappet 53a and lever 63 is present. In order to provide for an almost constant pre-loading of the drive system, the lever 63 is pushed upwards here on the end, on which it comes into contact with the tappet 53a, by means of an actuator spring 70.

The tappet 53a is supported by means of the tappet spring 69 on a tappet bearing 71, which is adjoined to the bottom by a tappet seal 72. The tappet spring 69 pushes the tappet head 68 upwards here, away from the tappet bearing 71 in the axial direction. A tappet tip 73 is thus also pushed away from a sealing seat 74 of the nozzle 54. This means that without external pressure from the top onto the tappet head 68, a nozzle opening 55 is also unsealed in the rest state (non-expanded state) of the piezo actuator 2 (FIG. 2).

The supply of the metering substance D to the nozzle 54 takes place via a nozzle chamber 75 as well as an adjoining supply channel 56, which can be connected to a metering substance reservoir (not shown here) by means of a metering substance supply line 76.

The metering system 50, more precisely the housing block 57, furthermore comprises—as shown in FIGS. 2, 4, 6, 8 and 10 in an exemplary manner and schematically at different positions in the metering system 50—inlet openings 58i_{rad}, 58iₐₓ and outlet openings 58o_{rad}, 59o of a (non-illustrated) controllable cooling means, which openings have a direct or indirect connection to a bellows 10, 20, 30, 40 of the actuator module 1. A cooling medium M, e.g., air M, in particular compressed air or pre-cooled compressed air, can be introduced from the outside at a desired point, e.g., into the actuator chamber 58 via the respective inlet openings 58i_{rad}, 58iₐₓ.

It is shown in FIG. 2 that a cooling medium M flows via a radial inlet opening 58i_{rad} into the actuator chamber 58, which inlet opening 58i_{rad} is arranged essentially at a height hₑ or a here upper end section of a bellows 10 of the actuator module 1. The cooling medium M thus flows into the actuator chamber 58 in a region between a here upper front side 12 and a here lower front side 11 (FIG. 3) of the module housing 3 and impinges on the bellows 10 (FIG. 2) for the first time at the height hₑ. Due to the helix-shaped structure of the housing wall 3w, the cooling medium M, which flows in, is guided along the outer jacket surface of the bellows 10 through a groove 17, which is delimited by two elevations 18, and flows around the jacket surface in the helix-shaped region in a targeted manner. It can be seen that the respective elevations 18 adjoin a wall 58w or an inner jacket surface 58w of the actuator chamber 58 of the metering system 50, respectively, essentially in a flush manner. A directed flow of cooling medium M can thus be generated along the groove 17. Due to the contact with the jacket surface of the bellows 10, the cooling medium M absorbs heat, which is generated in the piezo actuator 2 during operation or which is present at the piezo actuator surface 2′, respectively, and which is guided via the potting compound 4, in particular via the auxiliary substance 4b in the potting compound 4a, in the module housing interior space 3i (FIG. 2) all the way to the module housing wall 3w or the jacket surface of the bellows 10, respectively, and leads it away from the actuator module 1. The bellows 10 can be cooled effectively hereby. After the cooling medium M has completely passed the jacket surface of the bellows 10 along the groove 17, it is discharged from, blown out o or sucked out of the actuator chamber 58 again via a radial outlet opening 58o_{rad}. The outlet opening 58o_{rad} is located essentially at a height h_{f} of a here lower end section of the bellows 10 of the module housing 3. The flow direction of the cooling medium M through the metering system 50 is shown schematically by means of arrows. The alignment of the radial inlet opening 58i_{rad} and of the radial outlet opening 58o_{rad} with respect to the axial direction R_{AX} and the radial direction R_{RAD} of the module housing 3 or of the actuator module 1, respectively, is furthermore shown in FIG. 2 on the basis of a schematic coordinate system. In the cross section in FIG. 1, the axial direction R_{AX}, which runs in the viewing direction, is shown schematically as center point of the actuator module 1, wherein the radial direction R_{RAD} runs transversely thereto. An azimuthal direction R_{AZ} is furthermore shown schematically in FIG. 1.

If necessary, the heated-up cooling medium M, which exits from the actuator chamber 58, can be supplied to a cooling means again for cool-down purposes, in order to be capable of being used once again subsequently for the cooling again via the inlet opening 58i_{rad}. Such a circuit with heat exchanger for outputting the absorbed heat is to be seen as an alternative for a compressed air cooling, in the case of which the used compressed air is subsequently not used further for the most part.

The actuator module 1 from FIG. 2 is shown in detail in FIG. 3, wherein the bellows 10 is constructed so that a single groove 17 extends constantly or continuously, respectively, over the entire length of a helix-shaped section 14. The helix-shaped section 14 or the beginning thereof, respectively, is arranged at a distance a₁₀ from the end side 12. In the example shown here, the opposite end of the helix-shaped section 14, which faces the front side 11, forms a ring-shaped elevation.

The module housing 3 in FIG. 3 is formed so that in the assembled state (FIG. 2), the cooling medium M, which is directed at or impinging on, respectively, the grooved jacket surface of the bellows 10, flows through a groove 17, which extends or winds, respectively, in a helix-shaped manner in a winding direction WR_{AX,AZ} along the bellows 10, which groove 17 is laterally delimited by means of parallel elevations 18 running on both sides of the groove 17. The groove 17 has a groove width 17b of preferably 1 mm, wherein the respective elevation 18 has an elevation width 18b of preferably 1 mm. Accordingly, a gradient 19s of the bellows 10 is 2 mm in this example. The module housing 3 furthermore comprises a here upper front-side ring flange 16 and a here lower end-side ring flange 15.

An exemplary embodiment of an actuator module 1 with a bellows 20, which is modified compared to FIG. 3, is shown in FIGS. 4 and 5, wherein the helix-shaped section 14 is arranged at a distance a₂₀ from the here upper front side 12 of the module housing 3. The helix-shaped section 14 adjoins a flat or winding-free section 22, respectively, pointing in the direction of the front side 12 here or transitions into a flat region 22, respectively. Accordingly, the housing 3 does not have a final ring-shaped elevation, in which the groove ends (unlike in the case of FIG. 3). Instead, the groove 17 ends in the flat section 22. The advantage of this design with a helix-shaped section tapering off freely, which ends in a flat section 22, lies in that the flow of the cooling medium can be directed essentially at any point along the circumference of the flat section 22, whereby the flow of cooling medium flows on its own into the groove 17, which is starting.

In the case of the groove 17 of the bellows 10 from FIG. 3, which is delimited by the ring-shaped elevation in the form of a “flange”, in contrast, a unique (target) entrance point for the cooling medium into the groove 17 is defined. If the cooling medium is introduced exactly at this point, it automatically flows into the groove 17 and along the groove 17 all the way to the end of the helix-shaped section 14. Should the cooling medium only be introduced into the groove 17 at a later point, however, a “dead” section can optionally be created, in which cooling medium may build up or accumulate, respectively.

In the case of the bellows 10 (see FIGS. 2 and 3) and the slightly modified bellows 20 (see FIGS. 4 and 5), it is advantageous when, as is the case here in FIGS. 2 and 4, the outlet opening 58o_{rad} is located at the opposite, other end section of the bellows 10, 20, viewed in the axial direction R_{AX} (FIG. 2), as the inlet opening 58i_{rad} because virtually the entire bellows 10, 20 is then cooled. As is shown in FIGS. 2 and 4, there is in each case an inlet opening 58i_{rad} in the region of an end section of the bellows 10, 20 just in front of a ring flange 16, 26 (FIGS. 3 and 5) close to the end side 12 of the module housing 3. An outlet opening 58o_{rad} is arranged in the region of the opposite, other end section of the bellows 10, 20 just in front of a ring flange 15, 25 (FIGS. 3 and 5) close to the front side 11 of the module housing 3 in the assembled state (FIGS. 2 and 4). With respect to the assembled bellows 10, 20, both openings 58i_{rad}, 58o_{rad} in each case end radially on the outer side in the region of a jacket surface section on the bellows 10, 20 and extend from there through and ultimately out of the housing block 57 of the metering system 50 to the cooling means in a radial direction R_{RAD} of the respective bellows 10, 20, which corresponds to the radial direction R_{RAD} of the respective actuator module 1.

In FIGS. 2 and 4, the radial inlet opening 58i_{rad} as well as the radial outlet opening 58o_{rad} are in each case located in an exemplary manner on a right side of the housing block 57 in the azimuthal direction R_{AZ} of the bellows 10, 20.

As has already been explained, the bellows 20 illustrated in FIG. 4 (as well as furthermore also in FIG. 10 in the case of an exemplary embodiment of the metering system 50, which will be explained further below) differs only slightly from the bellows 10 from FIG. 3. The difference lies in the design of the wave contour 10, 20 of the end sections in front of the front sides 11, 12 of the module housing 3 of the respective bellows 10, 20. In the case of the bellows 10, the wave contour 10 ends in front of the respective ring flange 15, 16 with a groove 17, which is closed towards a ring seal 61 (see FIG. 2), i.e., the end of the groove 17 is delimited by the elevation 18. In other words, the helix-shaped section 14 of the wave contour 10 in each case concludes on both opposite ends with a ring-shaped elevation section as part of an elevation 18 and is thus separated with respect to the respective ring flange 15, 16 (which, in the installed state of the actuator module 1, serves as a ring seal 61 to the front side 11 or as a ring seal 61 to the end side 12 of the module housing 3, respectively, as stop).

In the case of the housing module 3 in FIGS. 4 and 5, in contrast, the groove 17 tapers off freely at the respective end of the helix-shaped section 14 (illustrated here, for example, with left-handed helix or winding, respectively) at the bellows 20 to the respective ring seal 61 (see FIG. 4) in a wider, flat section 21, 22, which lies just in front of a ring flange 25, 26 and which starts at a distance a₂₀ from the here upper front side 12 (FIG. 5). Compared to the ring flange 26, the lower ring flange 25 in FIGS. 4 and 5 protrudes less strongly at the other, opposite end section. This means that the elevation 18 delimiting the groove 17 already tapers off approximately one winding before. In the installed state, the way to the front sides 11, 12 between the surface of the bellows 20 and the wall 58w or inner jacket surface 58w, respectively, of the actuator chamber 58 is thus only sealed by the ring seal 61 but not by the elevation 18 itself (FIG. 5) at the bellows 20.

In the case of further exemplary embodiments of a metering system 50 according to the invention in FIGS. 6 and 8, which each have an actuator module 1 according to the invention, which is installed as intended, with a bellows 30, 40, two radial outlet openings 58o_{rad} are in each case arranged at the height hₑ, h_{f} of an end section of the bellows 30, 40. A radial inlet opening 58i_{rad}, which is assigned to a central section 33 of the assembled bellows 30 (FIG. 6), is arranged between the external outlet openings 58o_{rad} at the height hₘ or at a height hₘ, respectively, which is assigned to a central, flat section 43 of the bellows 40 in the housing block 57 (FIG. 8).

The exemplary embodiments shown in more detail in FIGS. 7 and 9 of the actuator module 1 from FIGS. 6 and 8 with the bellows 30, 40 differ from the exemplary embodiments (FIGS. 3 and 5), which have already been described above, in that the wave contour 30, 40 over its axial extension comprises two separate helix-shaped sections 34l, 34r (FIG. 7) or 44l, 44r (FIG. 9), respectively, instead of a continuous helix-shaped section 14. The respective helix-shaped sections 34l, 34r, 44l, 44r of the respective bellows 30, 40 in FIGS. 7 and 9 are in each case approximately half as long as the continuous helix-shaped section 14 of the bellows 10 of the actuator module 1 in FIG. 3. They each extend from a central section 33 (FIG. 7) or from a flat central section 43 (FIG. 9), respectively, to the end sections of the respective bellows 30, 40.

In the case of the bellows 30 in FIG. 7, the helix-shaped section 34l ends with a ring-shaped elevation 18 just in front of an end-side ring flange 35, which again serves as stop for a ring seal 61 (see FIG. 6), in the vicinity of the front side of the bellows 30. The other helix-shaped section 34r at the other end region ends just in front of a front-side ring flange 36 in the vicinity of the end side 12, in particular at a distance ago from the end side 12 of the module housing 3 of the bellows 30. In the central section 33, the two grooves 17 of the two helix-shaped sections 34, 34r meet each other or intersect one another, respectively, exactly in an end point or dead center, respectively. The two helix-shaped sections 34l, 34r and thus also the respective assigned grooves 17 have a different winding direction (FIG. 7).

It can be seen in FIG. 6 that in the assembled state of the actuator module 1, the inlet opening 58i_{rad} of the metering system 50 is directed at a dividing point, which is offset slightly with respect to the dead center or point of intersection, respectively, of the two grooves 17 described on the basis of FIG. 7 and which is located approximately a quarter turn in front of this dead center in the azimuthal direction R_{AZ}, at which dead center the two helix-shaped sections 34l, 34r split up into two grooves 17. With the positioning of the inlet opening 58i_{rad} and of the actuator module 1 to one another, which is shown in FIG. 6, it is attained that the cooling medium flows equally into both grooves 17 and flows along them in the direction of the outlet openings 58o_{rad} and as little cooling medium as possible flows in the opposite direction to the end point or dead center, respectively, of the two grooves 17 thereby.

The bellows 40 in FIG. 9 comprises two helix-shaped sections 44l, 44r with a different winding direction, wherein the two grooves 17 also have different helical directions. In the case of this bellows 40, a (here lower) helix-shaped section 44l ends at the end section of the bellows 40 in a short, flat or winding-free section 41 (without elevations), respectively, which is delimited by a ring-shaped elevation, which runs purely in the azimuthal direction R_{AZ} and which is adjoined on the front side (i.e., on the side of the elevation facing the front side) by a positioning groove for a ring seal 61 (see FIG. 8), which, in turn, is delimited by a ring flange 45 (in the vicinity of the front side of the bellows 40) as stop to the front side.

The other helix-shaped section 44r at the other end region of the bellows 40 is formed identically. There, the helix-shaped section 44r transitions at a distance a₄₀ from the end side 12 of the module housing 3 of the bellows 40 into a flat or winding-free section 42, respectively, which is adjoined, again—this time on the end side—by a ring-shaped elevation, which is delimited, in turn, at a distance from a ring seal 61 (FIG. 8) by a ring flange 46 as stop to the end side 12.

Said central, flat section 43 separates the two helix-shaped sections 44l, 4l in the center of the bellows 40 in FIG. 9, so that the sections 44l, 44r are spaced apart from one another at a distance b₄₀. Over the full distance b₄₀, the central section 43 is groove-and elevation-free. However, the distance b₄₀ between the sections 44l, 44r can vary along the circumference of the module housing 3. As shown in FIG. 8, the actuator module 1 is arranged in the metering system 50 so that the inlet opening 58i_{rad} is located in the wall 58w of the actuator chamber 58 of the housing block 57 at the height hm of the central section 43 in order to introduce the cooling medium M from the right here on the right side into the actuator chamber 58. The cooling medium M can generally also be introduced into the actuator chamber 58 from a different side.

Due to the fact that the inlet opening 58i_{rad} is in each case located in the center between the two outlet openings 58o_{rad} in FIGS. 6 and 8, the region of the piezo actuator 2 (FIG. 2), which heats up the most during operation, namely the center, can be cooled the most because the cooling medium M is introduced there so as to still be freshly cooled. Towards the respective end, the piezo actuator 2 also usually heats up less during operation, so that increasingly less cooling is required here. This is why a sufficient cooling of the piezo actuator 2 can also be achieved at the ends in spite of a heat-up of the cooling medium M as a result of a flow-around of the bellows 30, 40 towards the end regions. The cooling degree or the cooling power, respectively, can thus also correlate with the heating degree of the piezo actuator 2 and thus the jacket surface of the bellows 30, 40 here.

In the case of the actuator modules 1 in FIGS. 7 and 9, the sections 34l, 44l have a left-handed helix or winding direction WR_{AX,AZ}, respectively, and the sections 34r, 44r have an opposing right-handed helix or winding direction WR_{AX,AZ}. The sections 34l, 34r, 44l, 44r winding in opposite directions have the advantage that they can in each case halve torsional forces, which may appear during operation of the metering system and can also cancel each other out directly due to the opposing winding direction WR_{AX,AZ}. This is so because in the case of a cylindrical body, torsional forces can possibly ensure a twisting of the cylinder with increasing radius and/or increasing length of the thread section with unidirectional winding, depending on the material properties and material thickness. The construction-related reduction of this effect expands the options for the material selection and material thickness.

A further exemplary embodiment of a metering system 50 according to the invention is shown in FIG. 10, in the case of which the cooling medium M is introduced from an axial direction into the metering system 50 and which can manage without the ring seals 61, which are described, e.g., on the basis of FIG. 4 (if they are present nonetheless, they only take on a rough adjusting function for the actuator module 1 in the housing 57 here). This is so because the cooling medium M is ultimately admitted at these points into a groove 17 of the bellows 20* on the end side at the bellows 20* through a surface cutout in or along, respectively, the adjacent wall 58w of the recess 58* of the housing 57 of the metering system 50 via an axial inlet opening 58iₐₓ past the outside of the ring flange 26 of the bellows 20*.

An alternative variation for this is shown in FIG. 11, in the case of which the housing 57 surrounding the actuator module 1, more precisely the recess 58 in the housing 57, does not have the mentioned cutout, but the upper end section as well as the ring flange 26 of the bellows 20* has four module housing edge recesses 3a, which are drilled out or milled out concavely here, e.g., and through which the cooling medium M reaches or flows, respectively, into the actuator chamber 58*.

For this purpose, a lateral milled slot in the form of a concave or semi-spherical cut-out, respectively, can concretely be introduced into the end side 12 and/or the ring flange 26, for example by means of a ball cutter or a drill, so that the cooling medium M can reach from the inlet opening 58iₐₓ or supply bore, respectively, via this lateral expansion or these lateral expansions, respectively, in the wall 58w of the recess 58* into the helix or helix-shaped groove 17, respectively.

It subsequently flows in or along, respectively, the helix-shaped groove 17 before it flows axially or on the front side, respectively, out of the actuator chamber 58* into an action chamber 59 as further recess 59 at the opposite end section of the bellows 20 past the ring flange 25, in which action chamber for instance the lever 63 of a transmission mechanism 60 is located, wherein the setup of the transmission mechanism 60 has been described on the basis of FIG. 2. The axial letting in and letting out of the cooling medium has the particular advantage that the entire cooling with supply and exhaust air can thus be accommodated on the installation space of the cross sectional surface of the actuator cooling and a corresponding metering system or metering valve, respectively, can thus be made in a highly space-saving, in particular narrow manner, which is a large advantage especially in the case of applications with several metering systems, which are arranged in parallel, tightly next to one another. In addition, the cooling medium M also flows through the action chamber 59 in the region of this transmission mechanism 60, before it is guided out of the housing block 57, e.g., in to the cooling means (not illustrated) in the region of the tappet device 53 at the height of the actuator spring 70 or tappet spring 69, respectively, through an outlet opening 590 laterally (here to the right) through a bore in the housing block 57.

The flow-through from the inlet opening 58iₐₓ at the end side 12 of the module housing 3 of the bellows 20 all the way to the outlet opening 59o in the region of the transmission mechanism 60 or of the tappet device 53, respectively, has the advantage that material abrasion, etc., which is created during the operation of the metering system 50, can also be directly flushed out of the system. If this is the case, it lends itself to filter the cooling medium M accordingly after each pass-through, at least when it is used again.

FIGS. 12 and 13 now also show an actuator module 1 with a tubular, elastic or expandable/stretchy sheath 47, respectively. The sheath 47 is mounted onto the actuator module 1 once for the metering operation or the actuator module 1 is alternatively sheathed therewith. Due to the casing in the form of the sheath 47 around the actuator module 1, the groove 17, which is delimited by means of the lateral elevations 18, of the bellows 20** of the actuator module 1 becomes a closed, tightly helically extending tunnel, through which the cooling medium M can be guided so as to be led all-around. At the two axial end regions, the sheath 47 comprises a respective opening, to which a hose 48, 49 for the cooling medium M is vulcanized. This has the advantage that the housing 57 of the metering system 50 itself does not have to include these channels in the form of actual bores.

By means of the sheath 47, which sits tightly on the elevations 18, it is prevented that cooling medium M can jump over or flow over the elevations 18, respectively, perpendicular to the winding direction WR_{AX,AZ} of the groove 17. In the installed state, in which the actuator module 1 is inserted and installed with the sheath 47 in the metering system 50, an exactly fitting, virtually tight enclosure of the actuator module 1 by means of the surrounding housing 57 or the actuator chamber 58 in the housing 57, respectively, is then no longer required. FIG. 13 shows a variation of the actuator module 1 from FIG. 12, but without the elongated supply hoses 48, 49. Instead, corresponding bores or supply hoses are then located in the housing of the corresponding metering system, which is not illustrated explicitly here, however.

By means of the cooperation of the potting compound 4 with the auxiliary substance 4b in the interior of the actuator module 1 with the design of the wave contour 10, 20, 30, 40 on the surface of the actuator module 1 according to the invention as well as the cooling medium inlets and outlets of the metering system 50, a particularly efficient heat dissipation from the piezo actuator 2 can take place during operation of the metering system 50, which can have an advantageous effect on the metering precision and the service life of the piezo actuator 2.

In closing, it is pointed out once again that the devices described in detail above are only exemplary embodiments, which can be modified in a large variety of ways by the person of skill in the art without leaving the scope of the invention. For example, actuator modules illustrated in the exemplary embodiments are thus also conceivable with other gradients and/or winding directions of the helix-shaped sections of the bellows. The use of the indefinite articles “a” or “an”, respectively, furthermore does not rule out that the respective features can also be present several times. The terms “element” and “arrangement” likewise do not rule out that the respective component consist of several cooperating partial components, which can optionally also be spatially distributed.

### LIST OF REFERENCE NUMERALS

1 actuator module
2 piezo actuator/actuator
2′ piezo actuator surface
3 module housing
3i module housing interior space
3w module housing wall
3a module housing edge recess
4 potting compound
4a base compound/substance
4b auxiliary substance
5 control means
5′ connection cable
6a terminal/contact pin (piezo actuator)
6b terminal/contact pin (temperature sensor)
7a actuator module control terminals
7b temperature sensor terminals
10, 20, 20*, 20**, 30, 40 bellows/wave contour
11 front side
12 front side/end side
14 section, helix-shaped
15 ring flange, end side
16 ring flange, front side
17 groove/depression
17b groove width
18 elevation
18b elevation width
19s gradient
21,22 section, flat
25,26 ring flange
33 central section
34l section with left-handed helix
34r section with right-handed helix
35 ring flange, end side
36 ring flange, front side
41,42 section, flat
43 central section, flat
44l section with left-handed helix
44r section with right-handed helix
45,46 ring flange
47 sheath
48 supply hose
49 discharge hose
50 metering system
51 actuator assembly
52 fluidic assembly
53 tappet device
53a ejection or closing element/tappet
54 nozzle
55 nozzle opening
56 supply channel
57 housing/housing block
58,58* recess/actuator chamber
58w walls/inner jacket surface of the actuator chamber
58iₐₓ inlet opening, axial
58i_{rad} inlet opening, radial
58o_{rad} outlet opening, radial
59 further recess/action chamber
59o outlet opening, further in the region of the ejection element
60 transmission mechanism
61 ring seal
62 screw
63 transmission lever/lever
64 pressure piece
65 lever bearing
66 contact surface (lever)
67 contact surface (tappet head)
68 tappet head
69 tappet spring
70 actuator spring
71 tappet bearing
72 tappet seal
73 tappet tip
74 sealing seat
75 nozzle chamber
76 metering substance supply line
a₁₀, a₂₀, a₃₀, a₄₀ distance
b₄₀ distance/free space between the helix-shaped sections
hₑ height/position of an upper end section of the bellows
h_{f} height/position of a lower end section of the bellows
hₘ height/center between the end sections of the bellows
AR ejection direction
D metering substance/metering medium
K tilt axis
M cooling medium/air
R_{AX} axial direction
R_{RAD} radial direction
R_{AZ} azimuthal direction
WR_{AX,AZ} winding direction

1. A actuator module (1) with a hermetically sealed module housing (3), which extends longitudinally in an axial direction (R_{AX}), with at least one piezo actuator (2) arranged in the module housing (3) and with electrical terminals (6a, 6b) at least for the piezo actuator (2), which terminals (6a, 6b) are fed through a module housing wall (3w), wherein a module housing interior space (3i) between the piezo actuator (2) and the module housing wall (3w) comprises a potting compound (4), which electrically insulates the module housing wall (3w) from the piezo actuator (2) and which is formed in a heat-conducting manner, in particular with a heat-conducting auxiliary substance,
wherein the module housing wall (3w) of the module housing (3) has a bellows (10, 20, 30, 40) with a wave contour (10, 20, 30, 40),
wherein at least one section (14, 34l, 34r, 44l, 44r) of the wave contour (10, 20, 30, 40) is formed in a helix-shaped manner in the axial direction (R_{AX}).

2. The actuator module according to claim 1, wherein the potting compound (4) comprises a base compound (4a) and an auxiliary substance (4b),
wherein the base compound (4a) is preferably a cured substance (4a) and the auxiliary substance (4b) is at least particulate, heat-conducting and dielectric,
wherein the auxiliary substance (4b) is arranged in the potting compound (4) so that a heat dissipation from the piezo actuator (2) to the module housing wall (3w) takes place during operation via the potting compound (4), in particular via the auxiliary substance (4b).

3. The actuator module according to claim 1, wherein in the axial direction (R_{AX}), the helix-shaped section (14, 34l, 34r, 44l, 44r) in each case starts at a distance (a₁₀, a₂₀, a₃₀, a₄₀) from a respective front side (11, 12) of the module housing (3) and in each case extends from there to the other front side (12, 11) at least in sections, preferably at least to a center of the bellows (10, 20, 30, 40).

4. The actuator module according to claim 1, wherein in a respective end region close to the respective front side (11, 12), the module housing wall (3w) of the module housing (3) has flat sections (21, 22, 41, 42), in each case adjacent to the helix-shaped section (14, 34l, 34r, 44l, 44r) on the end side.

5. The actuator module according to claim 1, wherein the module housing wall (3w) of the module housing (3) and/or the bellows (20*) hast at least one module housing edge recess (3a), preferably four module housing edge recesses (3a), wherein the at least one module housing edge recess (3a) particularly preferably has a concave cross section.

6. The actuator module according to claim 1, wherein in an axial direction (R_{AX}) the bellows (30, 40) has at least two helix-shaped sections (34l, 34r, 44l, 44r) running in opposite directions, wherein preferably at least two of the helix-shaped sections (34l, 34r, 44l, 44r) are separated from one another, particularly preferably with a winding direction (WR_{AX,AZ}) running in opposite directions.

7. The actuator module according to claim 1, wherein at least two helix-shaped sections (34l, 34r, 44l, 44r) are separated from one another by means of a flat section (43), which is preferably arranged in the center of the bellows (40), from which they in each case extend in the axial direction (R_{AX}) to the front sides (11, 12).

8. The actuator module according to claim 1, wherein at least one helix-shaped section (14, 34l, 34r, 44l, 44r) of the bellows (10, 20, 30, 40) has a gradient (19s) of at least 1 mm, preferably at least 5 mm, particularly preferably at least 10 mm,
and/or
maximally 35 mm, preferably maximally 20 mm, particularly preferably maximally 15 mm.

9. The actuator module according to claim 1, with a tubular sheath (47), wherein the sheath (47) has at least two openings.

10. A metering system (50) for a metering substance (D) with a nozzle (54) for outputting metering substance (D), a supply channel (56) for metering substance (D), an ejection element (53a) and at least one actuator module (1), which is coupled to the ejection element (53a),
wherein the metering system (50) has a housing (57) with at least one cylindrical recess (58, 58*), in which the actuator module (1) according to claim 1 is inserted, preferably so as to fit accurately, during a metering operation,
wherein for cooling purposes, the housing (57) has an inlet opening (58iₐₓ, 58i_{rad}) into the recess (58, 58*) for introducing a cooling medium (M) into a groove (17) on the outer side of the bellows (10, 20, 30, 40) as well as at least one outlet opening (58o_{rad}) from the recess (58, 58*) for discharging the cooling medium (M) from a groove (17).

11. The metering system according to claim 10, wherein the recess (58) of the metering system (50) has at least one radial inlet opening (58i_{rad}) and/or a radial outlet opening (58i_{rad}), which, in the case of an actuator module (1), which is installed in the metering system (50), with module housing (3), are located preferably essentially at a height (hₑ) of an upper end section and/or at a height (h_{f}) of a lower end section of the module housing (3).

12. The metering system according to claim 10, wherein at least one of the walls (58w), which axially delimits the recess (58, 58*) of the housing (57), has an inlet opening (58iₐₓ) or an outlet opening, or wherein one of the walls (58w) has an inlet opening (58iₐₓ) and the other wall has an outlet opening.

13. The metering system according to claim 10, wherein in the case of an actuator module (1), which is installed as intended, the recess (58) has an inlet opening (58i_{rad}) in the center between the front sides (11, 12) of the module housing (3) in a radial wall (58w), for introducing the cooling medium (M).

14. The metering system according to claim 10, wherein in the case of a metering system (50) with a transmission mechanism (60), which is arranged in a further recess (59) between the piezo actuator (2) and the ejection element (53a), an outlet opening (59o) is arranged in the region of the transmission mechanism (60) and/or of the ejection element (53a),
and/or
wherein at least one inlet opening (58iₐₓ) is formed at an axial end region of the bellows (10, 20, 30, 40) for introducing the cooling medium (M), preferably from an axial direction (R_{AX}).

15. The metering system according to claim 10, preferably in the case of a metering system (50) with an inlet opening (58iₐₓ) at an end region of the bellows (10, 20, 30, 40) at the end side of the piezo actuator (2), the housing (57) has a further recess (59), which preferably extends transversely thereto, on the front side of the piezo actuator (2) and in which a transmission lever (63) is arranged, which transmits the longitudinal expansion of the piezo actuator (2) via a lever arm of the transmission lever (63) to the ejection element (53a) of a resiliently mounted tappet device (53),
wherein the outlet opening (59o) for the cooling medium (M) is arranged in the region of the further recess (59) close to the resiliently mounted tappet device (53).

16. The actuator module according to claim 6, wherein at least two helix-shaped sections (34l, 34r, 44l, 44r) are separated from one another by means of a flat section (43), which is preferably arranged in the center of the bellows (40), from which they in each case extend in the axial direction (R_{AX}) to the front sides (11, 12).
